(19) United States
(12) Patent Application Publication
(10) Pub. No.: US 2018/0090653 A1
(43) Pub. Date: Mar. 29, 2018

(54) HEAT DISSIPATING PLATE DEVICE FOR LIGHT EMITTING DIODE, HEAD LAMP FOR AUTOMOBILE AND METHOD FOR PREPARING THE SAME

(71) Applicants: HYUNDAI MOTOR COMPANY, Seoul (KR); KIA MOTORS CORPORATION, Seoul (KR); THE BOARD OF REGENTS OF THE NEVADA SYSTEM OF HIGHER EDUCATION ON BEHALF OF THE UNIVERSITY OF NE, Las Vegas, NV (US)

(72) Inventors: Byung Kyu CHO, Seoul (KR); Yool Koo KIM, Ansan-si (KR); Bong Jun ZHANG, Chestnut Hill, MA (US); Kwang Jin KIM, Henderson, NV (US)

(21) Appl. No.: 15/809,662

(22) Filed: Nov. 10, 2017

Related U.S. Application Data
(62) Division of application No. 14/520,917, filed on Oct. 22, 2014.

(51) Int. Cl. B32B 17/10; H01L 33/64

(52) U.S. Cl. CPC H01L 33/641; H01L 2933/0075

(57) ABSTRACT

A heat dissipating plate for a light emitting diode (LED) includes a metal thin film containing a hydroxyl functional group (—OH). A coating layer is disposed on at least one surface of the metal thin film and includes a carbon nanotube containing a hydrophilic functional group. The coating layer is attached to the metal thin film by bonding the hydroxyl functional group with the hydrophilic functional group in a hydrogen bond.

### RELATED APPLICATIONS

This application is Divisional of U.S. patent application Ser. No. 14/520,917, filed on filed Oct. 22, 2014, the disclosure of which is incorporated by reference herein.

### BACKGROUND OF THE DISCLOSURE

### (a) Technical Field

The present disclosure relates to a heat dissipating plate for a light emitting diode (LED), a head lamp for an automobile including the same, and a method for preparing the same.

### (b) Description of the Related Art

As generally known, an electronic member generating a lot of heat includes a high power amplifier (HPA) and a linear power amplifier (LPA) of a mobile communication repeater, a central processor unit (CPU) of a personal computer, a multiple processor unit (MPU) of a server-level work station, a power amplifier unit (PAU) of a relay base station, and so on. For these electronic members, a surface temperature is increased due to the heat generated by being driven in the maximum load. The malfunction and the breakage possibility are also highly increased due to the overheat phenomenon of the electronic members.

Representative devices, which discharge heat from an electronic equipment in order to prevent malfunction and the breakage, mainly use a fin heat sink for discharging heat generated from the heat source by a heat dissipating fin and a heat pipe for discharging heat generated from the heat source through a capillary structure to move heat outside.

However, the fin heat sink may increases the fin density or increase the length of the heat dissipating fin for maximizing the heat dissipating area, but the cooling efficiency is deteriorated when increasing the fin density, and the heat dissipating plate is enlarged when increasing the length or size of heat dissipating fin, so the manufacturing cost is also increased.

In addition, the cost for expansion of facilities for the heat pipe is relatively expensive, thus, the mass production thereof is difficult.

### SUMMARY

An aspect of the present disclosure provides a heat dissipating plate for a light emitting diode (LED) having a light-weight and an improved cooling performance.

Another aspect of the present disclosure provides a head lamp for an automobile including a heat dissipating plate for an LED.

Further, another aspect of the present disclosure provides a method of preparing a heat dissipating plate in a low cost and a high efficiency.

According to an embodiment of the present disclosure, a heat dissipating plate for an LED includes a metal thin film containing a hydroxyl functional group (—OH). A coating layer is disposed on at least one surface of the metal thin film and includes a carbon nanotube containing a hydrophilic functional group.

Bonding energy of the hydrogen bond may be about 15 KJ/mol to 40 KJ/mol.

The hydrophilic functional group may be a carboxyl functional group (—COOH).

A thickness of the coating layer may be about 10 to 100 μm.

An average diameter of the carbon nanotube may be about 10 to 30 nm.

An average length of the carbon nanotube may be about 1 to 20 μm.

The metal thin film may be selected from aluminum, iron, copper, nickel silver, tin, zinc, tungsten, and a combination thereof.

The metal thin film may further include a plurality of protruded heat dissipating fins.

The heat dissipating fins may be selected from aluminum, iron, copper, nickel silver, tin, zinc, tungsten, and a combination thereof.

A head lamp for an automobile including the heat dissipating plate is provided.

The head lamp may further include a cooling fan.

According to another embodiment of the present disclosure, a method of preparing a heat dissipating plate for an LED includes oxidizing a carbon nanotube in an acid aqueous solution. The oxidized carbon nanotube is neutralized, and an ultra-sonication is treated to provide a carbon nanotube dispersion. A metal thin film is immersed in the carbon nanotube dispersion and heated to coat the carbon nanotube on the metal thin film.

The dispersion may further include a dispersing agent selected from sodium dodecyl sulfate, lithium dodecyl sulfate, TRITON®-X, and a combination thereof.

The heating may be performed at a heat capacity of about 150 to 400 W/cm² for about 30 minutes to 2 hours.

The coating layer is attached to the metal thin film by bonding the hydroxyl functional group with the hydrophilic functional group in a hydrogen bond.

According to embodiments of the present disclosure, the heat dissipating plate for an LED is light-weight and has excellent cooling characteristics due to a high thermal conductivity.

### BRIEF DESCRIPTION OF THE DRAWINGS

FIG. 1 is a schematic view showing a chemically non-treated carbon nanotube, a functionalized carbon nanotube and damaged/opened carbon nanotube.

FIGS. 2 and 3 are scanning electron microscopic (SEM) photographs of the functionalized carbon nanotube, illustrating a fused carbon nanotube and an entangled carbon nanotube, respectively.

FIG. 4 is a graph showing the cooling performance results of heat dissipating plates obtained from Example 1, Comparative Example 1, and Comparative Example 2 in terms of a temperature change according to an applied power.

FIG. 5 is a graph showing cooling performance results of heat dissipating plates obtained from Example 2, Comparative Example 1, and Comparative Example 2 in terms of a temperature change according to an applied power.

FIG. 6 is a graph showing a temperature difference (ΔT) change of between a base temperature (T_{base}) and a tip temperature (Tₜᵢₚ) of a heat dissipating fin for a heat dissipating plate obtained from Example 1 depending upon time.

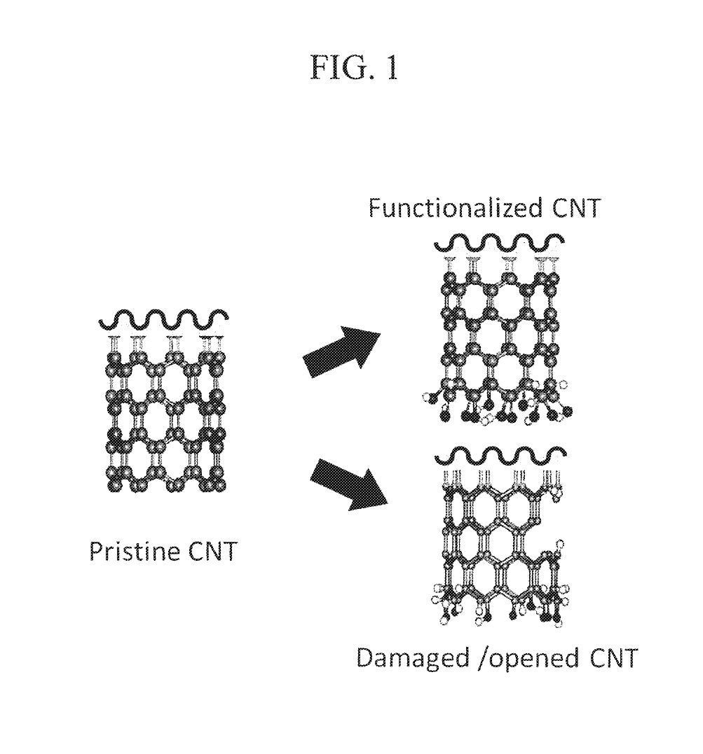

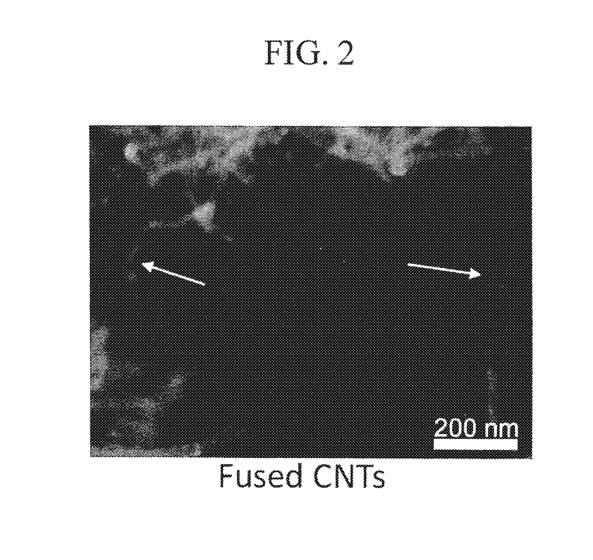

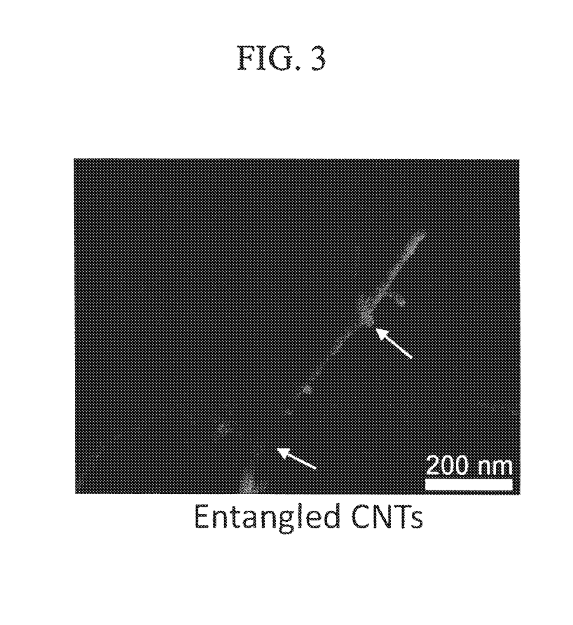

### DETAILED DESCRIPTION

Hereinafter, embodiments of the present disclosure are described in detail. However, these embodiments are exemplary, and thus, the disclosure is not limited thereto.

According to an embodiment of the present disclosure, a heat dissipating plate for an LED may include a metal thin film containing a hydroxyl functional group (—OH). A coating layer is disposed on at least one surface of the metal thin film and includes a carbon nanotube containing a hydrophilic functional group. The coating layer may be attached to the metal thin film by bonding the hydroxyl functional group with the hydrophilic functional group in a hydrogen bond.

As the carbon nanotube is light-weight and has a high length to diameter ratio, it has a very high surface area per unit area and characteristics of a physical strength of almost 100 times of steel and is chemically stable. Particularly, the carbon nanotube has a thermal conductivity of about 1600-6000 W/mK, which is more excellent than copper (thermal conductivity: about 400 W/mK) or aluminum (thermal conductivity: about 205 W/mK) as several ten to several hundred times. Accordingly, when the carbon nanotube having the very high surface area and a thermal conductivity compared to the conventional material is included in at least one surface of the metal thin film, the heat exchange efficiency may be enhanced through the surface where the carbon nanotube is disposed.

Bonding energy of the hydrogen bond may be about 15 KJ/mol to 40 KJ/mol. Specifically, the strong bond between functional groups may be provided by an electrostatic attractive force induced by the hydrogen bond, without any additional adhesive layer.

Therefore, a process for providing the additional adhesive layer is not necessary, so a process simplification and a weight-reduction of the heat dissipating plate may be accomplished.

The hydrophilic functional group may be a carboxyl functional group (—COOH).

A thickness of the coating layer may be about 10 to 100 μm.

When the coating layer has a thickness of less than 100 μm, a region where the metal thin film is not coated with a carbon nanotube coating layer may be existed, so a uniform heat radiation may be not accomplished. Specifically, the thickness of the coating layer may be about 10 to 50 μm, and more specifically about 10 to 30 μm.

The metal thin film may include any metal having a high thermal conductivity, and may include a pure metal or an alloy. Specifically, the metal thin film may include a pure metal including one kind of metal selected from aluminum (Al), iron (Fe), copper (Cu), nickel (Ni), silver (Ag), tin (Sn), zinc (Zn), and tungsten (W) or the like, or an alloy of at least two kinds of metals selected from the metals list above. Specifically, the metal thin film may include the pure metal selected from Al, Cu, Sn, or the alloy thereof, considering the cost, the weight, the thermal conductivity, or the like. It may further include a pure aluminum or an aluminum alloy thin film including a main component of aluminum.

The thickness of the metal thin film may be freely established depending upon the electronic product, ranging from about 0.01 mm to 5.0 mm. More specifically, the metal thin film for a laptop computer may have a thickness of less than or equal to about 0.1 mm, or ranging from about 0.01 mm to 0.1 mm. The metal thin film for a plasma display may have a thickness of greater than or equal to about 0.1 mm, or ranging from about 0.1 mm to about 5.0 mm.

The metal thin film may have a shape comprising a plurality of protruded heat dissipating fins by modifying a flat metal thin film in order to increase a surface area and to maximize a heat transfer efficiency. The heat dissipating fin may be made of material selected from aluminum, iron, copper, nickel silver, tin, zinc, tungsten, or the like, which is the same as the material for metal thin film.

According to another embodiment of the present disclosure, a head lamp for an automobile may include a heat dissipating plate for an LED.

Still, according to another embodiment of the present disclosure, a method of preparing a heat dissipating plate for an LED includes oxidizing a carbon nanotube in an acid aqueous solution. The oxidized carbon nanotube is neutralized and treated with an ultrasonication to provide a carbon nanotube dispersion. A metal thin film is immersed in the carbon nanotube dispersion and heated to coat the carbon nanotube on the metal thin film.

According to an embodiment of the present disclosure, the heat dissipating plate having an improved cooling efficiency may be obtained by acid-treating and heating in an aqueous solution instead of a complicate anodizing treatment. The carbon nanotube may be a single-wall nanotube, a multi-walled nanotube, a rope nanotube, or a mixture thereof.

In an exemplary embodiment of the present disclosure, the carbon nanotube having a diameter of about 10 nm to 30 nm, a length of about 1 μm to 20 μm was used. A diameter of the carbon nanotube may be specifically about 10 to 20 nm, or about 10 nm to about 15 nm. A length of the carbon nanotube may be specifically about 1 to about 10 μm, or about 1 μm to about 5 μm.

The carbon nanotube may be functionalized by oxidizing the carbon nanotube in the acid aqueous solution. In other words, the hydrophilic functional group may be generated on a surface of the carbon nanotube to be well absorbed on a surface of the metal thin film. The hydrophilic functional group for providing a hydrogen bond with hydroxyl functional group on an aluminum surface may include a carboxyl functional group.

The generation of the hydrophilic functional group on the surface of the carbon nanotube may be optimized by adjusting pH of the acid aqueous solution within about 1 to 2. The functionalized carbon nanotube powder may be obtained by neutralizing the carbon nanotube acid aqueous solution in less than or equal to pH 7, distilling and drying the same.

In order to uniformly disperse the functionalized carbon nanotube powder in the aqueous solution, the dispersion may further include a dispersing agent. The dispersing agent may be selected from sodium dodecyl sulfate, lithium dodecyl sulfate, TRITON®-X, and a combination thereof. In an exemplary embodiment of the present disclosure, more specific examples may be sodium dodecyl sulfate.

In this case, the functionalized carbon nanotube and the dispersing agent may have a concentration of about 100 wppm, respectively. In other words, if water has a mass of about 1 g/ml at a room temperature, the functionalized carbon nanotube and the dispersing agent may be each used in 100 mg per 1 L of water. When the functionalized carbon nanotube and the dispersing agent are mixed at a set ratio, the carbon nanotube may be uniformly and strictly attached onto the metal thin film.

The ultrasonification may be generally sufficient in an intensity of about 40 to 60 KHz for about 1 hour as long as conditions do not give any damage on the functionalized carbon nanotube. On the other hand, when a dispersed phase offunctionalized carbon nanotube is uniformly dispersed in a dispersion medium of water, the solution may be black.

The coating the carbon nanotube on the metal thin film may be performed with heating as immersing the metal thin film in the dispersion solution. In this case, the heating may be performed at a heat capacity of about 150 to 400 W/cm² for about 0.5 to 2 hours. According to an embodiment of the present disclosure, the heating may be performed at a heat capacity of about 200 W/cm² for about 1 hour.

When the heating condition is as in above, the coating layer may have a desirable thickness.

The method of preparing a heat dissipating plate according to an embodiment of the present disclosure includes functionalizing the carbon nanotube and then heating in aqueous solution, which may simplify the process and save the cost. As the method does not require an additional process such as pre-treatment on the metal thin film for the carbon nanotube coating, the heat dissipating plate having an improved cooling efficiency may be provided by the simplified process.

The heat dissipating plate structure using the carbon nanotube according to an embodiment of the present disclosure may be equally applicable to a device of discharging heat by compression and condensation, for example, an air conditioner, a mechanical machine as well as to a computer cooler (computer processing unit (CPU) cooler, graphic card cooler, heat dissipating fin, and heat pipe self-cooler) including a laptop.

Hereinafter, examples of the present disclosure and comparative examples are described. These examples, however, are not in any sense to be interpreted as limiting the scope of the inventive concept.

### EXAMPLE

### Synthesis Example 1

### Preparation of Chemically-Treated Carbon Nanotube (CNT)

36% hydrochloric acid and multi-walled CNTs (MWCNTs) were mixed and neutralized, and then distilled and dried for 12 hours to provide a functionalized CNT.

The functionalized CNT was ground, and then 100 wppm of functionalized CNT was added into 100 wppm of sodium dodecyl sulphate (SDS) aqueous solution and mixed for 1 hour through an ultrasonication to provide a functionalized CNT-SDS disperse solution.

### Example 1

### Preparation of CNT Deposited Heat Dissipating Plate

A aluminum heat dissipating plate was immersed in the functionalized CNT-SDS disperse solution obtained from Synthesis Example 1 and heated for 1 hour with applying a heat capacity of about 200 W/cm², and then taken out and washed with distilled water to provide a heat dissipating plate.

The obtained heat dissipating plate was evaluated for a cooling performance.

### Example 2

### Preparation of Heat Dissipating Plate Mounted with Cooling Fan

The heat dissipating plate was evaluated for the cooling performance in accordance with the same procedure as in Example 1, except that the heat dissipating plate according to Example 1 was used in a device mounted with a cooling plate.

### Comparative Example 1

### Preparation of Heat Dissipating Plate without Surface Treatment

The aluminum heat dissipating plate was used without a separate treatment.

### Comparative Example 2

### T_{HMG}

The heat dissipating plate was obtained from Hyundai Motor Company, which is mass-produced and surface-treated according to aluminum anodizing method.

### Evaluation Example 1

### Evaluating Cooling Performance of Heat Dissipating Plate

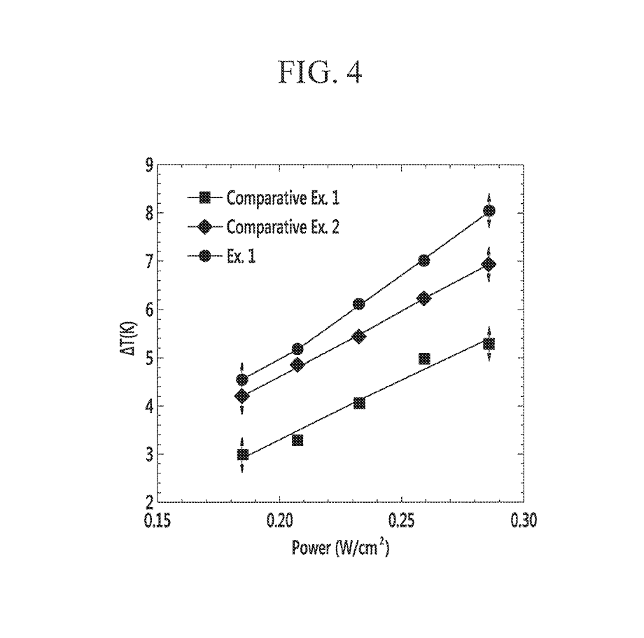

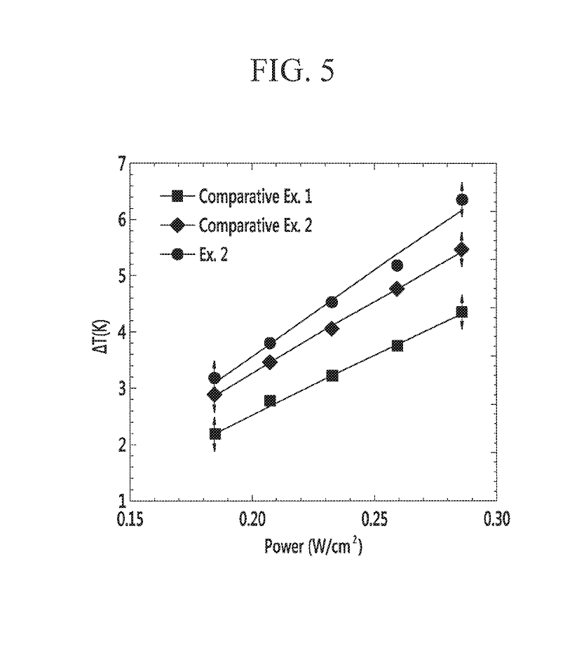

The heat dissipating plates according to Example 1, Example 2, Comparative Example 1, and Comparative Example 2 were evaluated for the cooling performance, and the results are shown in FIGS. 4 and 5.

FIG. 4 is a graph showing cooling performance results of the heat dissipating plate obtained from Example 1, Comparative Example 1, and Comparative Example 2 in terms of a temperature change depending upon power applied. FIG. 5 is a graph showing cooling performance results of the heat dissipating plates obtained from Example 2, Comparative Example 1, and Comparative Example 2 in terms of a temperature change depending upon power applied.

T_{base}=124° C. was set as a base temperature of the heat dissipating fin in the heat dissipating plate, T₀=25° C. (air temperature) was set for air temperature. A temperature difference (ΔT=T_{base}−Tₜᵢₚ) between the base temperature and the tip temperature of heat dissipating fin depending upon the applied power was measured and shown in the graphs.

As ΔT is higher depending upon the applied power, the heat is more effectively transmitted.

Referring to FIG. 4 and FIG. 5, it is understood that Example 1 and Example 2 had a higher temperature difference (ΔT) depending upon the applied power than Comparative Example 1 and Comparative Example 2. Particularly, the cooling performance is improved about 18% to 27% according to Example 1 and about 17% to 38% according to Example 2, compared to the heat dissipating plate obtained by surface-treating in the aluminum anodizing method. In other words, it is confirmed that the heat dissipating plates according to Examples 1 and 2 had a further excellent heat discharging efficiency from the results, and the difference between the base temperature (T_{base}) and the tip temperature (Tₜᵢₚ) was relatively large.

### Evaluation Example 2

### Evaluation of Cooling Stability Of Heat Dissipating Plate

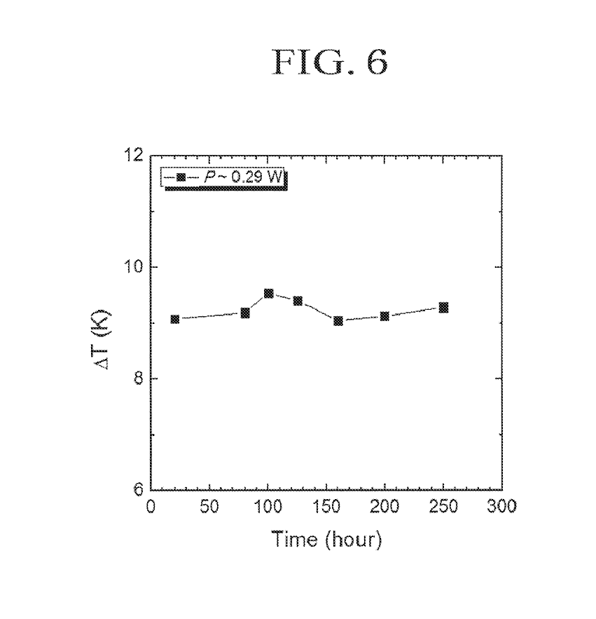

In order to determine whether the heat dissipating plate obtained from Example 1 may maintain the cooling characteristics in the same level for a long period of time, the heat dissipating plate was evaluated for the cooling performance with power of 0.29 W for 250 hours, and results are shown in FIG. 6.

FIG. 6 is a graph showing the difference (ΔT) change of base temperature (T_{base}) and tip temperature (Tₜᵢₚ) of heat dissipating fin of the heat dissipating plate obtained from Example 1 depending upon the time.

Referring to FIG. 6, it is confirmed that the average ΔT is maintained in about 9.25 K with an error range of ±0.18 K.

While this invention has been described in connection with what is presently considered to be practical exemplary embodiments, it is to be understood that the invention is not limited to the disclosed embodiments, but on the contrary, is intended to cover various modifications and equivalent arrangements included within the spirit and scope of the appended claims.

What is claimed is:

1. A method of preparing a heat dissipating plate for an LED comprising steps of:
oxidizing a carbon nanotube in an acid aqueous solution;
neutralizing the oxidized carbon nanotube and then treating an ultrasonication to provide a carbon nanotube dispersion; and
immersing a metal thin film in the carbon nanotube dispersion and heating the same to coat the carbon nanotube on the metal thin film.

2. The method of claim 1, wherein the dispersion further comprises a dispersing agent selected from sodium dodecyl sulfate, lithium dodecyl sulfate, Triton-x, and a combination thereof.

3. The method of preparing a heat dissipating plate of claim 1, wherein the step of heating the metal thin film is performed with a thermal capacity of about 150 to 400 W/cm² for about 0.5 to 2 hours.
